(19) United States
(12) Patent Application Publication
(10) Pub. No.: US 2017/0273223 A1
(43) Pub. Date: Sep. 21, 2017

(54) COOLING SYSTEM FOR ELECTRONIC EQUIPMENT

(71) Applicant: ExaScaler Inc., Tokyo (JP)

(72) Inventor: Motoaki SAITO, Chiyoda-ku, Tokyo (JP)

(21) Appl. No.: 15/506,707

(22) PCT Filed: Aug. 4, 2015
(86) PCT No.: PCT/JP2015/073757

§ 371 Date: Feb. 24, 2017

(30) Foreign Application Priority Data
Aug. 25, 2014 (JP) 2014-170616

(51) Int. Cl. H05K 7/20; H01L 23/44

(52) U.S. Cl. CPC H05K 7/20772; H05K 7/20236; H05K 7/20836; H01L 23/44; H05K 7/20272

(57) ABSTRACT

A cooling system is adapted for reduction of evaporative loss of a liquid coolant and for efficient cooling of plural electronic devices densely accommodated in a cooling bath of a small volume. A cooling system accommodates plural electronic devices in an open space of a cooling bath provided with an inlet port and an outlet port for a liquid coolant. The cooling system is configured to directly cool the electronic devices by immersion of the electronic devices in the liquid coolant circulated in the open space. The liquid coolant contains a perfluorinated compound as a main component. The liquid coolant is adapted to exhibit a liquid weight loss percentage of 1.5% or less as determined by allowing 10 ml of the liquid coolant in a 10-ml measuring cylinder (opening diameter: 11.5 mm) to spontaneously evaporate under normal environment at a room temperature of 25° C. for 100 hours.

### TECHNICAL FIELD

The present invention relates to a cooling system for electronic equipment. Particularly, the invention relates to a system for efficiently cooling electronic equipment such as supercomputer or electronic equipment at a data center which is required of ultrahigh performance operation and generates a large amount of heat per se.

### BACKGROUND ART

One of the largest issues deciding the performance limit of recent supercomputers is power consumption. The importance of studies concerning thrifty power consumption of the supercomputer has already received wide recognition. Namely, speed performance per unit power consumption (Flops/W) is regarded as one evaluation index of supercomputer. It is reported that about 45% of the total power consumption of the data center is consumed for cooling. There is a growing demand for reducing the power consumption by increasing cooling efficiency.

Conventionally, an air cooling system and a liquid cooling system are used for cooling the supercomputers or the data centers. The liquid cooling system is generally evaluated as having excellent cooling efficiency because of the use of a liquid having much higher heat transfer performance than air. For example, “TSUBAME-KFC”, a supercomputer constructed by Tokyo Institute of Technology has achieved 4.50 GFlos/W by virtue of a liquid immersion cooling system employing synthetic oil. This supercomputer has attained first place for high speed performance per unit power consumption in the November 2013 issue and the June 2014 issue of “Supercomputer Green 500 List”. However, a synthetic oil having high viscosity is used as a liquid coolant and hence, it is quite difficult to completely remove the adherent oil from electronic devices extracted from an oil immersion rack. This leads to an extremely complicated maintenance work for the electronic devices (specifically, adjustment, inspection, repair, part replacement, and expansion. The same applies hereinafter.). Further, it is reported that the synthetic oil used in the cooling system may leak as corroding packing and the like constituting the cooling system in the short term, so as to adversely affect the operation of the cooling system.

On the other hand, a liquid immersion cooling system has been proposed which employs a fluorocarbon-based liquid coolant instead of the synthetic oil causing above-described problem. Specifically, this cooling system exemplifies a case where a hydrofluoroether (HFE) compound commercially available from 3M Limited as “Novec (trade name of 3M Limited, the same applying hereafter) 7100”, “Novec 7200” or “Novec 7300” is used as the fluorocarbon-based liquid coolant (see for example, Patent Literature 1, Patent Literature 2).

### CITATION LIST

### Patent Literature

PTL 1: Japanese Patent Application Laid-Open No. 2013-187251

PTL 2: Japanese Patent Application Laid-Open No. 2012-527109

### SUMMARY OF INVENTION

### Technical Problem

A cooling system disclosed in Patent Literature 1 employs a fluorocarbon-based liquid coolant having a boiling point of 100° C. or less because the system utilizes vaporization heat (latent heat) for cooling the electronic equipment. When the liquid coolant is vaporized by heat generated by devices mounted in the electronic equipment, the vaporization takes heat (vaporization heat (latent heat)) from the devices which in turn are cooled. Accordingly, the fluorocarbon-based liquid coolant may locally boil on the surface of a high-temperature device, producing air bubbles which form an insulation film. Hence, an excellent heat transfer capacity intrinsic to the liquid coolant may be impaired. The electronic devices used in the recent supercomputers, data centers and the like include a variety of objects to be cooled which include not only CPUs (Central Processing Unit) but also GPUs (Graphic Processing Unit), high-speed memories, chip sets, network units, bus switch units, SSDs (Solid State Drive) and the like. It is impracticable to equally cool all these cooling objects having different vaporizing temperatures. As for a cooling object on which the coolant is not vaporized, the cooling efficiency is extremely low.

In addition, the fluorocarbon-based liquid coolant having the boiling point of 100° C. or less is readily vaporized. This dictates the need for frequently replenishing the liquid coolant in the cooling system. Since the fluorocarbon-based liquid coolant is quite expensive in general, a maintenance cost for compensating for the evaporative loss of the liquid coolant is enormous. That is, a problem exists that the replenishment takes much time and labor.

The cooling system disclosed in Patent Literature 2 adopts a sealed module structure containing one or more heat generating electronic devices. Therefore, the whole mechanism for circulating the liquid coolant through the individual sealed modules is complicated. In addition, this cooling system is inferior in maintainability for the electronic device because it is not easy to extract the whole body of the electronic device from the sealed module.

It is therefore an object of the invention to solve the above-described problems of the prior art and to provide a cooling system which is adapted for notable reduction of the evaporative loss of liquid coolant and for efficient cooling of a plurality of electronic devices densely accommodated in a cooling bath of a small volume.

### Solution to Problem

For achieving the above object, the invention provides a cooling system which accommodates a plurality of electronic devices in an open space of a cooling bath provided with an inlet port and an outlet port for a liquid coolant and which directly cools the plural electronic devices by immersion of the electronic devices in the liquid coolant circulated in the open space, the cooling system having a structure wherein the liquid coolant contains a perfluorinated compound as a main component thereof and has a liquid weight loss percentage of 1.5% or less as determined by allowing 10 ml of the liquid coolant in a 10-ml measuring cylinder (opening diameter: 11.5 mm) to spontaneously evaporate under normal environment at a room temperature of 25° C. for 100 hours.

According to a preferred aspect of the invention, the cooling system may have an arrangement wherein the liquid coolant has a steam pressure of 1.0 kPa or less at room temperature of 25° C.

According to a preferred aspect of the invention, the cooling system may have an arrangement wherein the liquid coolant has a boiling point of 150° C. or more.

According to a preferred aspect of the invention, the cooling system may have an arrangement wherein the perfluorinated compound as the main component is a perfluorinated compound having a carbon number of 10 or more.

According to a preferred aspect of the invention, the cooling system may have a structure wherein a header connected to the inlet port and extended in a width direction of the cooling bath is disposed at a bottom of the cooling bath and is configured to be supplied with the liquid coolant via the inlet port and to eject the liquid coolant from a plurality of nozzles arranged thereon in arrays.

According to a preferred aspect of the invention, the cooling system may have a structure wherein the plural nozzles consist of a plurality of nozzle groups arranged in a longitudinal direction of the header with required spacing, and each of the nozzle groups consists of nozzles with ejection orifices radially dispersed.

According to a preferred aspect of the invention, the cooling system may have a structure wherein each of the plural nozzle groups corresponds to each of the plural electronic devices.

According to a preferred aspect of the invention, the cooling system may have a structure wherein the outlet port and the inlet port are interconnected via a flow passage, while at least one pump for moving the liquid coolant and one heat exchanger for cooling the liquid coolant are disposed in the flow passage.

### Advantageous Effects of Invention

According to the inventive cooling system, the perfluorinated compound has excellent features which include: high electric insulating property; high heat transfer capacity; inertness or high thermal and chemical stability; incombustibility; an ozone depleting potential of zero because of being an oxygen free compound; and the like. If the liquid coolant containing such a perfluorinated compound as the main component exhibits a liquid weight loss percentage of 1.5% or less as determined by allowing 10 ml of the liquid coolant in a 10-ml measuring cylinder (opening diameter: 11.5 mm) to spontaneously evaporate under normal environment at a room temperature of 25° C. for 100 hours, the liquid coolant is less prone to evaporation even in a case where the cooling bath defines an unsealed open space. Thus, the cooling system can notably reduce the evaporative loss of the liquid coolant. Since the cooling system is adapted to eliminate a potential fear of local boiling of the liquid coolant in the cooling bath, the high heat transfer capacity of the perfluorinated compound is not impaired by the boiling liquid coolant. Therefore, the cooling system can achieve the efficient cooling of the plural electronic devices densely accommodated in the cooling bath of a small volume. The cooling bath having the “open space” as exemplified herein also includes a cooling bath having a sealed structure simple enough not to impair the serviceability of the electronic devices. For example, a structure where a top board is removably attached to an opening of the cooling bath via a packing or the like is the simple sealed structure. In the case of the cooling bath having such a simple sealed structure, an effect to even further reduce the evaporation of the liquid coolant can be expected.

According to preferred embodiments of the invention, the cooling system is similarly adapted to decrease the evaporation of the liquid coolant even though the cooling bath defines the unsealed open space, thus achieving a notable reduction of the evaporative loss of the liquid coolant in the case where the liquid coolant has a steam pressure of 1.0 kPa or less at room temperature of 25° C., where the liquid coolant has a boiling point of 150° C. or more, or where the perfluorinated compound as the main component is a perfluorinated compound having a carbon number of 10 or more. In addition, the cooling system can eliminate the potential fear of local boiling of the liquid coolant in the cooling bath. While the cooling systems employing the conventional fluorinated compounds have encountered the following problems, the invention can solve every one of them.

(1) The boiling of the fluorinated compound involves a potential risk of generating an extremely harmful fluorinated compound such as hydrogen fluoride by reaction with trace amounts of ambient hydrogen or oxygen.
(2) Even though immersed in an inert liquid, some of the electronic devices operating at extremely high speeds have potential to be locally raised to high temperatures, encountering the boiling of a fluorocarbon compound.
(3) In the event of loss or decline of the cooling function due to a trouble of the cooling system, the liquid coolant may be raised in temperature beyond a design limit, resulting in the boiling of the fluorocarbon compound.
(4) In the case of dropout of some component of the electronic device or chassis in the cooling bath or the case of invasion of some external foreign substance into the cooling bath of an open structure, the liquid temperature of the cooling bath may be locally raised due to local stagnation of liquid circulation, resulting in the boiling of the fluorocarbon compound.

According to the preferred embodiment of the invention, the cooling system has the structure wherein the header connected to the inlet port and extended in the width direction of the cooling bath is disposed at the bottom of the cooling bath and is configured to be supplied with the liquid coolant via the inlet port and to eject the liquid coolant from the plurality of nozzles arranged thereon in arrays. In this case, the cooling system is adapted to circulate a cold liquid coolant throughout the whole space of the cooling bath, further enhancing the effect of direct cooling based on forced circulation of the liquid coolant.

According to the preferred embodiment of the invention, the cooling system has the structure wherein the plural nozzles consist of a plurality of nozzle groups arranged in the longitudinal direction of the header with required spacing, and each of the nozzle groups consists of nozzles with ejection orifices radially dispersed. In this case, the cooling system is adapted to more efficiently circulate the cold liquid coolant throughout the whole space of the cooling bath, even further enhancing the effect of direct cooling based on the forced circulation of the liquid coolant.

According to the preferred embodiment of the invention, the cooling system has the structure wherein each of the plural nozzle groups corresponds to each of the plural electronic devices. In this case, the cooling system is adapted to deliver uniform cooling performance for the individual electronic devices which are densely accommodated in the cooling bath.

According to the preferred embodiment of the invention, the cooling system has the structure wherein the outlet port and the inlet port are interconnected via the flow passage, while at least one pump for moving the liquid coolant and one heat exchanger for cooling the liquid coolant are disposed in the flow passage. In this case, the cooling system is adapted for continuous and stable operation by forming the flow passage where the liquid coolant discharged from the outlet port of the cooling bath is cooled by the heat exchanger and the cold liquid coolant is supplied to the inlet port of the cooling bath.

The object and advantages of the above invention and the other object and advantages thereof will be more clearly understood by way of the following description of the embodiments. It is noted, however, that the embodiments to be described as below are intended for purpose of illustration only and are not intended to limit the scope of the invention.

### BRIEF DESCRIPTION OF DRAWINGS

FIG. 1 is a longitudinal sectional view of a cooling system according to an embodiment of the invention;

FIG. 2 is a transverse sectional view of the cooling system according to the embodiment of the invention;

FIG. 3 is a graph showing measurement results of weight loss percentages of different liquid coolants;

FIG. 4 is a table of comparison of characteristic values of perfluorinated compounds; and

FIG. 5 is a schematic diagram showing a cooling system where a drive system and a coolant system are disposed in a flow passage interconnecting an outlet port and an inlet port of a cooling bath.

### DESCRIPTION OF EMBODIMENTS

A cooling system according to a preferred embodiment of the invention will hereinbelow be described in detail with reference to the accompanying drawings. The description of the embodiment is made on an example where 8 units of electronic devices in total are densely accommodated in a cooling bath. One unit of electronic device has a structure where 4 processor boards are arranged on one surface thereof, the processor board mounted with a plurality of processors. This example is intended for illustrative purpose and the number of processors per board or the type of the processor is arbitrary. Further, the number of electronic device units is arbitrary as long as two or more electronic device units are accommodated. Such number and type do not limit the configuration of the electronic device according to the invention.

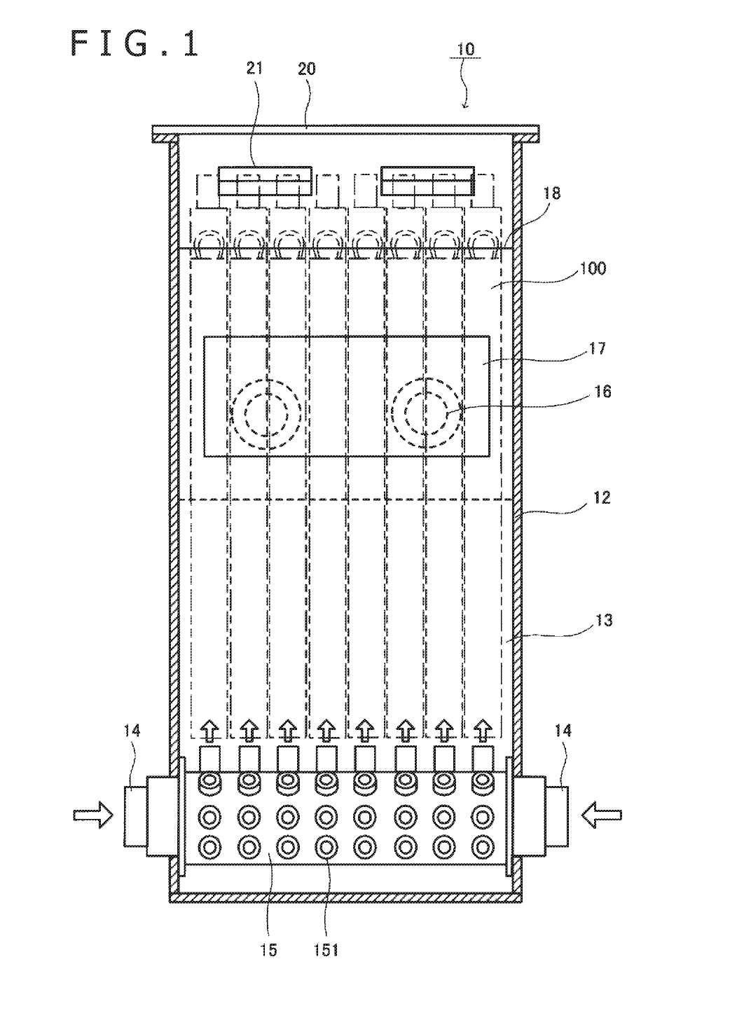

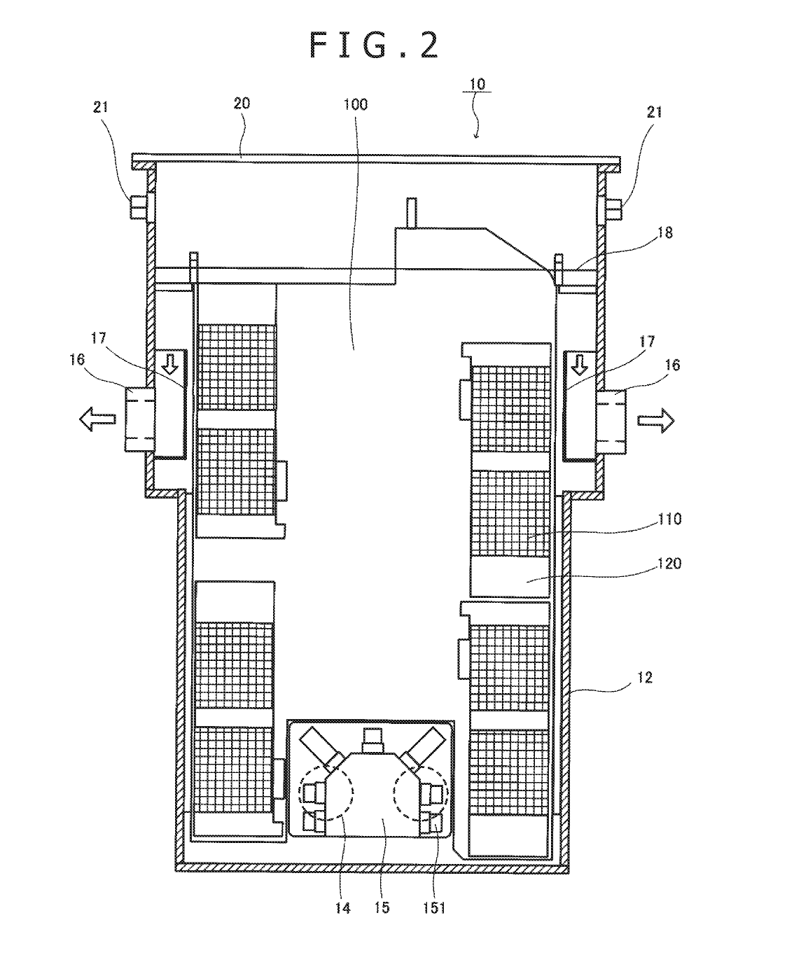

Referring to FIG. 1 and FIG. 2, a cooling system 10 includes a cooling bath 12. The cooling bath 12 is provided with two inlet ports 14 at each of a left-side bottom and a right-side bottom thereof and further provided with two outlet ports 16 at each place on a front side and a back side thereof. An open space in the cooling bath 12 accommodates 8 units of electronic devices 100 in total. The cooling bath 12 is configured to directly cool these electronic devices 100 by immersing these electronic devices in a liquid coolant 13 flowing in the open space. It is important to keep a liquid level 18 of the liquid coolant 13 high enough to ensure that all the heat generating components and parts of the electronic device 100 are immersed in the liquid coolant 13. According to the invention, the liquid level 18 is kept high for a long period of time because the liquid coolant 13 employed by the invention has a property of being very hard to evaporate as will be described hereinlater. In order to facilitate the maintenance work for the electronic device 100, a top board 20 is openably supported by means of an unillustrated hinge portion mounted to one edge of an upper opening of the cooling bath 12. Thus, the cooling bath 12 defines an open space of an unsealed structure. A variety of cables connected to the electronic device 100 can be drawn out from the cooling bath 12 as held together by a cable clamp 21.

A header 15 extended in a width direction (crosswise direction) of the cooling bath is disposed on a bottom of the cooling bath 12. One end of the header 15 is connected to the two inlet ports 14 at the left-side bottom of the cooling bath 12, while the other end of the header 15 is connected to the two inlet ports 14 at the right-side bottom of the cooling bath 12. The header includes a plurality of nozzles 151 arranged in arrays. The header is configured to eject the liquid coolant 13, as supplied through the right and left inlet ports 14, from these nozzles 151.

The nozzles 151 include plural nozzle groups arranged with required spacing in a longitudinal direction (crosswise direction) of the header 15. Each of the nozzle groups consists of the nozzles 151 arranged in a manner that their ejection orifices are radially dispersed on a surface of the header 15 having a hexagonal cross section.

On the cooling bath-12 side of the outlet ports 16 disposed in pairs on the front side and the back side of the cooling bath 12, a liquid guide plate 17 defines a region in a manner to cover the entire outlet ports 16 but forms an opening at an upper portion of the region. Therefore, the liquid coolant 13 flows from the upper opening toward the outlet ports 16.

The liquid coolant 13 used in the cooling system 10 consists primarily of a perfluorinated compound which has: high electric insulating property; high heat transfer capacity; inertness; high thermal and chemical stability; incombustibility; and an ozone depleting potential of zero. The liquid coolant 13 may be a single perfluorinated compound or a mixture of different perfluorinated compounds. It is important that the liquid coolant 13 has a liquid weight loss percentage of 1.5% or less. The liquid weight loss percentage is determined by: allowing 10 ml of liquid in a 10-ml measuring cylinder (opening diameter: 11.5 mm) to spontaneously evaporate under normal environment at a room temperature of 25° C. and calculating the weight loss percentage after a lapse of 100 hours.

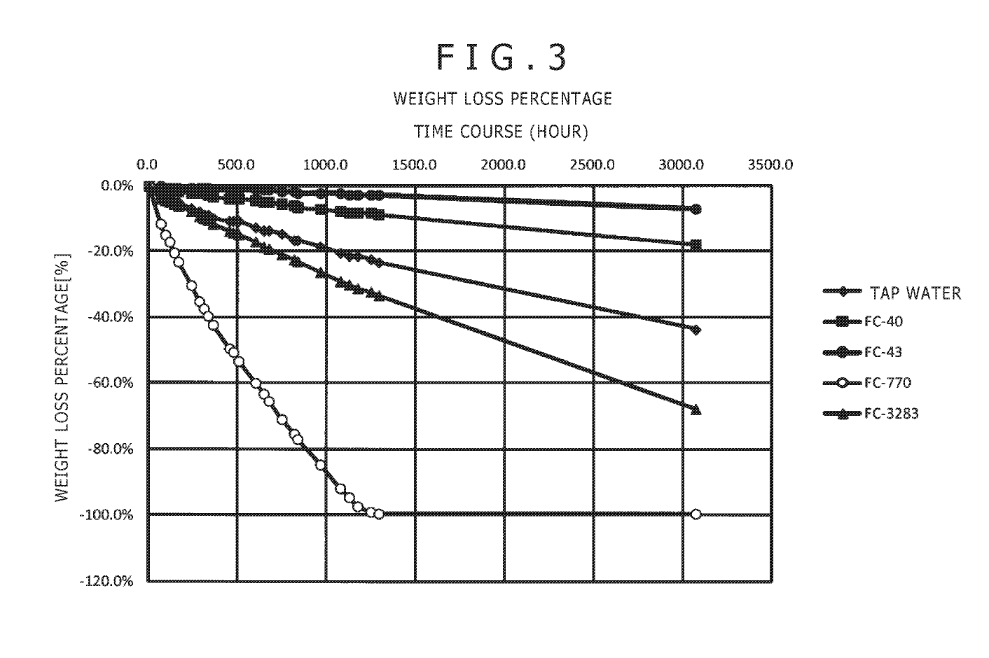

FIG. 3 shows a relation between the liquid weight loss percentage and the time course in an experiment where 10 ml of each of four types of perfluorinated compounds and tap water was put in the 10-ml measuring cylinder (opening diameter: 11.5 mm) and was allowed to spontaneously evaporate under the normal environment at room temperature of 25° C.

FC-40 denotes Fluorinert FC-40 (trade mark of 3M Limited.) commercially available from 3M Limited. Likewise, FC-43 denotes Fluorinert FC-43 commercially available from 3M Limited; FC-328 denoting Fluorinert FC-328 commercially available from 3M Limited; and FC-770 denoting Fluorinert FC-770 commercially available from 3M Limited. All these liquids are fluorine inert liquids based on a perfluorinated compound (perfluorocarbon compound), respectively. It is apparent from the gradient of weight loss percentage of FC-40 that FC-40 is much less prone to evaporation than tap water. It is also apparent that FC-43 is much less prone to evaporation than FC-40.

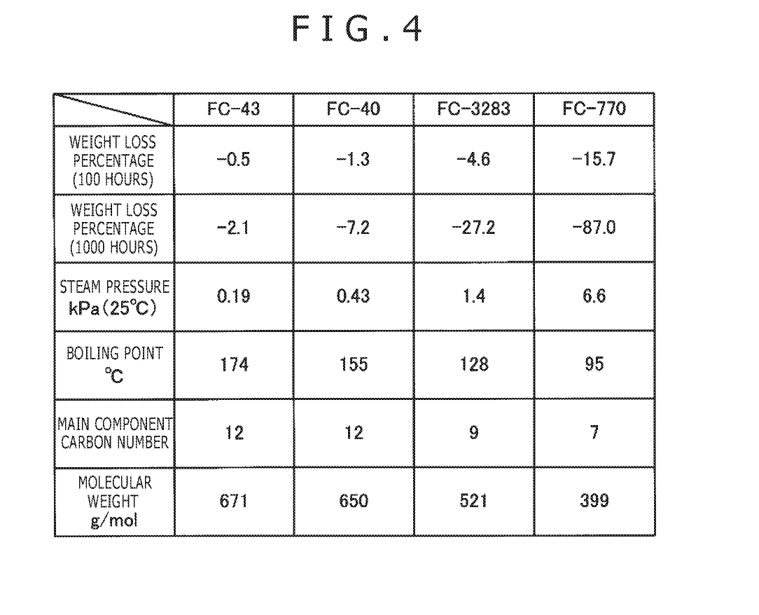

FIG. 4 is a table showing the results of comparison of FC-43, FC-40, FC-3283 and FC-770 in terms of weight loss percentage after a lapse of 100 hours, weight loss percentage after a lapse of 1000 hours, steam pressure, boiling point, carbon number of main component, and molecular weight.

It is experimentally found that a liquid coolant having a weight loss percentage of 1.5% or less after a lapse of 100 hours is less prone to evaporation even in a case where the cooling bath defines an unsealed open space. As suggested by the embodiment, it is important for the cooling bath 12 to adopt the unsealed structure such that the maintainability of the electronic devices is not impaired. It is found that the evaporative loss of the liquid coolant 13 can be notably reduced by employing FC-43 or FC-40.

It is also found that local boiling of the liquid coolant 13 on the surface of the processor 110 in the cooling bath 12, for example, can be effectively avoided by employing FC-43 or FC-40, as the liquid coolant, which has the weight loss percentage of 1.5% or less after a lapse of 100 hours. FC-43 and FC-40 afford a great advantage that the high heat transfer capacity of the perfluorinated compound is not impaired by boiling of the liquid coolant 13.

When the liquid coolant 13 has a steam pressure of 1.0 kPa at room temperature of 25° C., when the boiling point of the liquid coolant is 150° C. or more, or when the perfluorinated compound as the main component is a perfluorinated compound having a carbon number 10 or more, the liquid coolant 13 is also less prone to evaporation even in the case where the cooling bath defines the unsealed open space. Thus, the evaporative loss of the liquid coolant 13 can be notably reduced. Further, a potential fear of local boiling of the liquid coolant on the surface of the processor 110 in the cooling bath 12, for example, can be eliminated.

Next, the advantage of providing the header 15 in the cooling system 10 according to an embodiment of the invention is described with reference to FIG. 1 and FIG. 2.

The header 15 is configured to eject the liquid coolant 13, as fed through the inlet ports 14, from the plural nozzles 151 arranged in arrays on the header 15. Therefore, the header 15 can circulate the cold liquid coolant 13 (cooled by a heat exchanger, as will be described hereinlater) throughout the whole space of the cooling bath 12. Thus, the effect of direct cooling of the electronic devices 100 based on the forced circulation of the liquid coolant can be enhanced.

In addition, each of the nozzle groups longitudinally arranged on the header 15 with the required spacing consists of the nozzles 151, the ejection orifices of which are radially dispersed. Hence, the header is adapted to more efficiently circulate the cold liquid coolant 13 throughout the whole space of the cooling bath 12. Particularly as shown in FIG. 1 and FIG. 2, each of the plural nozzle groups corresponds to each of the plural electronic devices 100. Therefore, if the electronic devices 100 are densely accommodated in the cooling bath 12, the cooling system can deliver uniform cooling performance for each of electronic devices 100.

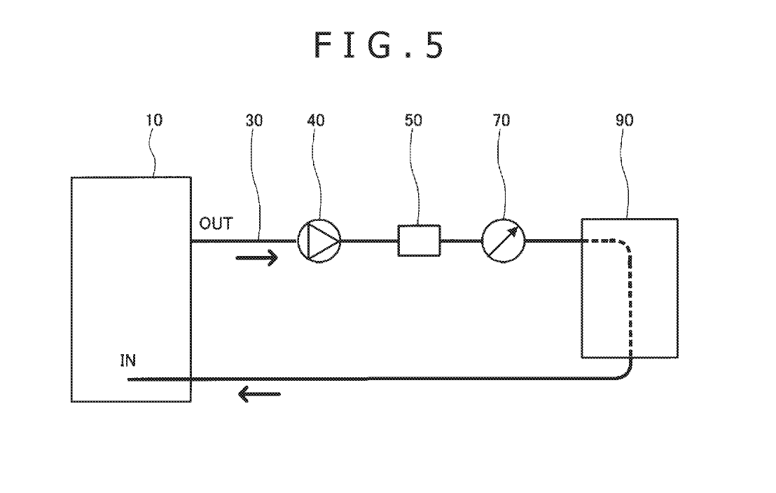

Lastly referring to FIG. 5, description is made on an example of configuration a flow passage where the liquid coolant discharged from the outlet ports of the cooling bath is cooled by the heat exchanger and then, the cold liquid coolant is supplied to the inlet ports of the cooling bath. As shown in the figure, the outlet ports 16 and the inlet ports 14 of the cooling bath 12 are interconnected by a flow passage 30, in which a pump 40 for moving the liquid coolant 13 and a heat exchanger 90 for cooling the liquid coolant 13 are disposed. A flow regulating valve 50 for regulating the flow rate of the liquid coolant 13 through the flow passage 30 and a flowmeter 70 are also disposed in the flow passage 30.

The pump 40 may preferably have a capability of moving a liquid having a relatively high kinetic viscosity (above 3 cSt at room temperature of 25° C.). This is because the kinetic viscosity of FC-43 is in the range of 2.5 to 2.8 cSt while that of FC-40 is in the range of 1.8 to 2.2 cSt. The flow regulating valve 50 may be a manually operable type or may be equipped with an adjustment mechanism for keeping a constant flow rate based on the measurement value determined by the flowmeter 70. Further, the heat exchanger 90 may be any of a variety of circulating heat exchangers (radiators or chillers) or coolers.

The cooling system 10 of the embodiment may further include: a first liquid temperature sensor (not shown) in the cooling bath 12 or the flow passage 30; and a mechanism (not shown) which is adapted to deactivate the electronic devices 100 or to power down the electronic devices 100 when the first temperature sensor detects a temperature exceeding a predetermined level. The addition of such a fail-safe mechanism can obviate the occurrence of abnormal temperature rise of the liquid coolant 13 above the set temperature and prevent the breakage of the electronic device and the generation of a harmful compound from fluorocarbon.

Further, the fail-safe mechanism may have another configuration. The cooling system of the embodiment may also include: a second temperature sensor (not shown) disposed in the electronic devices 100 immersed in the cooling bath 12 or around the electronic devices 100 immersed in the cooling bath 12; and the mechanism (not shown) which is adapted to deactivate the electronic devices 100 or to power down the electronic devices 100 when the first temperature sensor detects a temperature exceeding a predetermined level.

According to the invention, the processor is illustrated as the electronic device 100. The processor may include either of or both of CPU and GPU and may further include unillustrated high-speed memory, chip set, network unit, PCI Express bus, bus switch unit, SSD, and power unit. The electronic device 100 may be a server including a blade server, rooter, memory device such as SSD.

### INDUSTRIAL APPLICABILITY

The invention is applicable to a wide variety of cooling systems for efficiently cooling a plurality of electronic devices densely accommodated in the cooling bath of a small volume.

### REFERENCE SIGNS LIST

10: cooling system
12: cooling bath
13: liquid coolant
14: inlet port
15: header
151: nozzle
16: outlet port
17: liquid guide plate
18: liquid level
20: top board
21: cable clamp
30: flow passage
40: pump
50: flow regulating valve
70: flowmeter
90: heat exchanger
100: electronic device
110: processor (with radiator)
120: processor board

1. A cooling system which accommodates a plurality of electronic devices in an open space of a cooling bath provided with an inlet port and an outlet port for a liquid coolant and which directly cools the plural electronic devices by immersion of the electronic devices in the liquid coolant circulated in the open space, wherein the liquid coolant contains a perfluorinated compound as a main component thereof and has a liquid weight loss percentage of 1.5% or less as determined by allowing 10 ml of the liquid coolant in a 10-ml measuring cylinder (opening diameter: 11.5 mm) to spontaneously evaporate under normal environment at a room temperature of 25° C. for 100 hours.

2. The cooling system according to claim 1, wherein the liquid coolant has a steam pressure of 1.0 kPa or less at room temperature of 25° C.

3. The cooling system according to claim 1, wherein the liquid coolant has a boiling point of 150° C. or more.

4. The cooling system according to claim 1, wherein
the perfluorinated compound as the main component is a perfluorinated compound having a carbon number of 10 or more.

5. The cooling system according to claim 1, wherein
a header connected to the inlet port and extended in a width direction of the cooling bath is disposed at a bottom of the cooling bath and is configured to be supplied with the liquid coolant via the inlet port and to eject the liquid coolant from a plurality of nozzles arranged thereon in arrays.

6. The cooling system according to claim 5, wherein
the plural nozzles consist of a plurality of nozzle groups arranged in a longitudinal direction of the header with required spacing, and each of the nozzle groups consists of nozzles with ejection orifices radially dispersed.

7. The cooling system according to claim 6, wherein
each of the plural nozzle groups corresponds to each of the plural electronic devices.

8. The cooling system according to claim 1, wherein
the outlet port and the inlet port are interconnected via a flow passage, while at least one pump for moving the liquid coolant and one heat exchanger for cooling the liquid coolant are disposed in the flow passage.

9. The cooling system according to claim 1, further comprising:
a first liquid temperature sensor disposed in the cooling bath or the flow passage; and a mechanism which deactivates the electronic devices or power downs the electronic devices in a case where the first temperature sensor detects a temperature higher than a predetermined level.

10. The cooling system according to claim 1, further comprising:
a second temperature sensor disposed in the electronic devices immersed in the cooling bath or disposed around the electronic devices immersed in the cooling bath; and a mechanism which deactivates the electronic devices or power downs the electronic devices in a case where the second temperature sensor detects a temperature higher than a predetermined level.
